(19) United States
(12) Patent Application Publication
(10) Pub. No.: US 2024/0258291 A1
(43) Pub. Date: Aug. 1, 2024

(54) DISPLAY DEVICE

(71) Applicant: LG DISPLAY CO., LTD., Seoul (KR)

(72) Inventors: HyeSeon EOM, Seoul (KR); Juhyun NAM, Seoul (KR)

(73) Assignee: LG DISPLAY CO., LTD., Seoul (KR)

(21) Appl. No.: 18/421,394

(22) Filed: Jan. 24, 2024

(30) Foreign Application Priority Data
Jan. 31, 2023 (KR) 10-2023-0012951

(51) Int. Cl. H01L 25/16; H01L 25/075; H01L 27/12; H01L 33/10; H01L 33/62

(52) U.S. Cl. CPC H01L 25/167; H01L 25/0753; H01L 27/1244; H01L 27/1255; H01L 33/10; H01L 33/62

(57) ABSTRACT

A display device includes a substrate that has a display area in which a plurality of sub-pixels are disposed and a non-display area. The display device further includes a first assembly line and a second assembly line disposed in the plurality of sub-pixels on the substrate and spaced apart from each other. The display device further includes a light emitting element disposed on the first assembly line and the second assembly line. The display device further includes a plurality of transistors disposed in the plurality of sub-pixels. Each of the plurality of sub-pixels includes a first area in which the plurality of transistors are disposed and a second area which is separated from the first area and in which the light emitting element is disposed.

### CROSS-REFERENCE TO RELATED APPLICATION

This application claims the priority of Korean Patent Application No. 10-2023-0012951 filed on Jan. 31, 2023, which are hereby incorporated by reference in its entirety

### BACKGROUND

### Field of the Disclosure

The present disclosure relates to a display device, and more particularly, to a display device capable of improving light extraction efficiency of a light emitting diode (LED).

### Description of the Background

Display devices used in computer monitors, TVs, and mobile phones include organic light emitting displays (OLEDs) that emit light by themselves, and liquid crystal displays (LCDs) that require a separate light source.

Display devices are being applied to various fields of application including not only computer monitors and TVs, but also personal mobile devices, and thus, display devices having a reduced volume and weight while having a wide display area are being studied.

In recent years, display devices including light emitting diodes (LEDs) have received attention as next-generation display devices. Since the LED is formed of an inorganic material rather than an organic material, it has excellent reliability and has a longer lifespan compared to a liquid crystal display device or an organic light emitting display device. In addition, the LED has a high lighting speed, high luminous efficiency and excellent stability due to high impact resistance and may display a high-luminance image.

### SUMMARY

Accordingly, the present disclosure is to provide a display device capable of improving light extraction efficiency of a light emitting element.

The present disclosure is also to provide a display device in which an influence of an electric field generated in a light emitting element assembly process on a pixel circuit is minimized.

The present disclosure is not limited to the above-mentioned, and other features, which are not mentioned above, may be clearly understood by those skilled in the art from the following descriptions. Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device according to an exemplary aspect of the present disclosure includes a substrate including a display area in which a plurality of sub-pixels are disposed and a non-display area; a first assembly line and a second assembly line disposed in the plurality of sub-pixels on the substrate and spaced apart from each other; a light emitting element disposed on the first assembly line and the second assembly line; and a plurality of transistors disposed in the plurality of sub-pixels, wherein each of the plurality of sub-pixels includes a first area in which the plurality of transistors are disposed and a second area which is separated from the first area and in which the light emitting element is disposed. Therefore, luminous efficiency of the light emitting element may be improved.

According to the present disclosure, it is possible to minimize an influence of an electric field generated in a self-assembly process on a pixel circuit and prevent damage to the pixel circuit.

According to the present disclosure, it is possible to improve light extraction efficiency of a light emitting element.

The effects according to the present disclosure are not limited to the contents exemplified above, and further various effects are included in the present disclosure. Also, it is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a schematic configuration diagram of a display device according to an exemplary aspect of the present disclosure;

FIG. 2 is an enlarged plan view of the display device according to an exemplary aspect of the present disclosure;

FIG. 3 is a cross-sectional view taken along A-A′ and B-B′ of FIG. 2;

FIG. 4 is a cross-sectional view of a pad area of the display device according to an exemplary aspect of the present disclosure; and

FIG. 5 is a cross-sectional view of a display device according to another exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is referred to as being “on” another element or layer, it may be directly on the other element or layer, or intervening elements or layers may be present therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

Like reference numerals generally denote like elements throughout the specification.

A size and a thickness of each component illustrated in the drawings are illustrated for convenience of explanation, and are not limited to the size and the thickness of the component illustrated in aspects of the present disclosure.

The features of various aspects of the present disclosure may be partially or entirely coupled to or combined with each other and may be interlocked and operated in technically various ways, and respective aspects may be carried out independently of or in association with each other.

Other detailed matters of the exemplary aspects are included in the detailed description and the drawings.

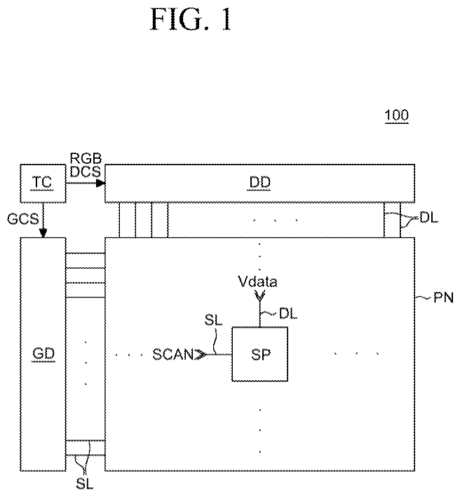

FIG. 1 is a schematic configuration diagram of a display device according to an exemplary aspect of the present disclosure.

For convenience of explanation, only a display panel PN, a gate driver GD, a data driver DD, and a timing controller TC among various components of a display device 100 are shown in FIG. 1.

Referring to FIG. 1, the display device 100 includes the display panel PN that includes a plurality of sub-pixels SP, the gate driver GD and the data driver DD that supply various signals to the display panel PN, and the timing controller TC that controls the gate driver GD and the data driver DD.

The display panel PN is configured to display images to a user and includes the plurality of sub-pixels SP. In the display panel PN, a plurality of scan lines SL and a plurality of data lines DL intersect each other, and each of the plurality of sub-pixels SP is connected to the scan line SL and the data line DL. In addition, each of the plurality of sub-pixels SP may be connected to high-potential power supply lines VDD, low-potential power supply lines, a reference line RL, and the like.

The plurality of sub-pixels SP are minimum units constituting a screen, and each of the plurality of sub-pixels SP includes a light emitting element and a pixel circuit for driving the light emitting element. A plurality of the light emitting elements may be defined differently depending on a type of display panel PN. For example, when the display panel PN is an inorganic light emitting display panel, the light emitting element may be a light emitting diode (LED) or a micro-light emitting diode (micro-LED).

The gate driver GD supplies a plurality of scan signals SCAN to the plurality of scan lines SL according to a plurality of gate control signals GCS provided from the timing controller TC. In FIG. 1, it is illustrated that one gate driver GD is disposed to be spaced apart from one side of the display panel PN, but the number and arrangement of gate drivers GD are not limited thereto. For example, the gate driver GD may be disposed within the display area AA.

The data driver DD converts image data RGB input from the timing controller TC into a data voltage Vdata using a reference gamma voltage according to a plurality of data control signals DCS provided from the timing controller TC. The data driver DD may supply the converted data voltage Vdata to the plurality of data lines DL.

The timing controller TC arranges image data RGB input from the outside and supplies it to the data driver DD. The timing controller TC may generate the gate control signal GCS and data control signal DCS using synchronization signals input from the outside, such as dot clock signals, data enable signals, and horizontal/vertical synchronization signals. In addition, the timing controller TC may supply the generated gate control signal GCS and data control signal DCS to the gate driver GD and data driver DD, respectively, to drive the gate driver GD and data driver DD.

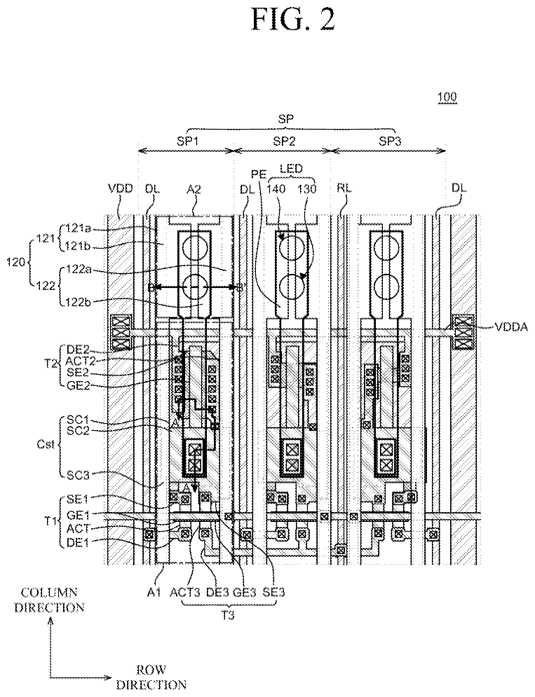

Hereinafter, a more detailed description of the display panel PN of the display device 100 will be provided with reference to FIGS. 2 to 4.

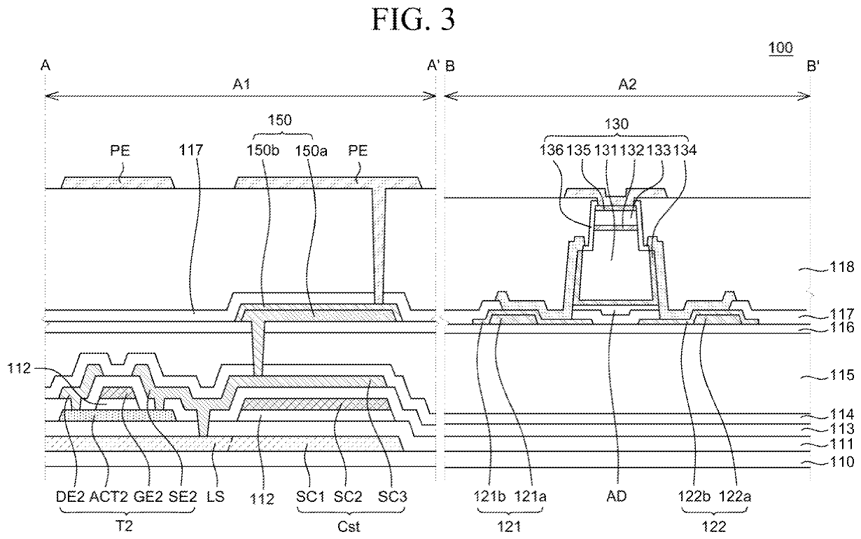

FIG. 2 is an enlarged plan view of the display device according to an exemplary aspect of the present disclosure. FIG. 3 is a cross-sectional view taken along A-A′ and B-B′ of FIG. 2. Referring to FIG. 2, each of the plurality of sub-pixels SP includes a first transistor T1, a second transistor T2, a third transistor T3, a storage capacitor Cst, and one or more light emitting elements LED. To drive this pixel circuit, a plurality of lines including the data lines DL, the high-potential power supply lines VDD, the scan lines SL, and the reference line RL are disposed on a first substrate 110. In FIG. 2, for the brevity of the drawing, hatching of assembly lines 120 and the light emitting elements LED is omitted, and a contact electrode CE is not shown.

Referring to FIG. 2, in the display device 100, the plurality of sub-pixels SP includes a first sub-pixel SP1 disposed in a first column, a second sub-pixel SP2 disposed in a second column, and a third sub-pixel SP3 disposed in a third column, and the first sub-pixel SP1, the second sub-pixel SP2, and the third sub-pixel SP3 are repeatedly disposed.

Each of the first sub-pixel SP1, the second sub-pixel SP2, and the third sub-pixel SP3 includes the light emitting element LED and the pixel circuit to independently emit light. For example, the first sub-pixel SP1 may be a red sub-pixel, the second sub-pixel SP2 may be a green sub-pixel, and the third sub-pixel SP3 may be a blue sub-pixel, but are not limited thereto. Referring to FIG. 2, the plurality of sub-pixels SP include a first area A1 in which a plurality of the pixel circuits and the storage capacitor Cst are disposed and a second area A2 which separates from the first area A1 and in which the light emitting element LED is disposed.

The pixel circuit may include the first transistor T1, the second transistor T2, the third transistor T3, and the storage capacitor Cst.

The display panel PN includes the substrate 110, a buffer layer 111, a gate insulating layer 112, an interlayer insulating layer 113, a first passivation layer 114, a first planarization layer 115, a second passivation layer 116, a third passivation layer 117, and a second planarization layer 118.

The substrate 110 is configured to support various components included in the display panel PN and may be formed of an insulating material. For example, the substrate 110 may be formed of glass or resin. Additionally, the substrate 110 may be formed of polymer or plastic, or may be formed of a material with flexibility.

The high-potential power supply lines VDD, the plurality of data lines DL, the reference line RL, the assembly lines 120, a light blocking layer LS, and first capacitor electrodes SC1 are disposed on the substrate 110.

The high-potential power supply line VDD is a line that transmits a high-potential power supply voltage to each of the plurality of sub-pixels SP. A plurality of the high-potential power supply lines VDD may transmit a high-potential power supply voltage to the second transistor T2 of each of the plurality of sub-pixels SP. The high-potential power supply line VDD may extend in a column direction between the plurality of sub-pixels SP. For example, the high-potential power supply line VDD may be disposed in the column direction between the first sub-pixel SP1 and the third sub-pixel SP3. Additionally, the high-potential power supply line VDD may transmit a high-potential power supply voltage to each of the plurality of sub-pixels SP disposed in a row direction through an auxiliary high-potential power supply line VDDA, which will be described later. In this case, the high-potential power supply line VDD may be referred to as a first power supply line. Additionally, the column direction may be referred to as a first direction, and the row direction may be referred to as a second direction.

The plurality of data lines DL are lines that transmit the data voltage Vdata to each of the plurality of sub-pixels SP. The plurality of data lines DL may be connected to the first transistor T1 of each of the plurality of sub-pixels SP. The plurality of data lines DL may extend in the column direction between the plurality of sub-pixels SP. For example, the data line DL extending in the column direction between the first sub-pixel SP1 and the high-potential power supply line VDD may transmit the data voltage Vdata to the first sub-pixel SP1. The data line DL disposed between the first sub-pixel SP1 and the second sub-pixel SP2 may transmit the data voltage Vdata to the second sub-pixel SP2. The data line DL disposed between the third sub-pixel SP3 and the high-potential power supply line VDD may transmit the data voltage Vdata to the third sub-pixel SP3.

The reference line RL is a line that transmits a reference voltage to each of the plurality of sub-pixels SP. The reference line RL may be connected to the third transistor T3 of each of the plurality of sub-pixels SP. The reference line RL may extend in the column direction between the plurality of sub-pixels SP. For example, the reference line RL may extend in the column direction between the second sub-pixel SP2 and the third sub-pixel SP3. In addition, a third drain electrode DE3 of the third transistor T3 of each of the first sub-pixel SP1, second sub-pixel SP2, and third sub-pixel SP3, adjacent to the reference line RL may extend in the row direction and may be electrically connected to the reference line RL. In this case, the reference line RL may be referred to as a third power supply line.

The light blocking layer LS is disposed on the substrate 110 in each of the plurality of sub-pixels SP. The light blocking layer LS may be disposed in the first area A1.

The light blocking layer LS may be disposed in an area overlapping a driving circuit in the first area A1 and block light incident on the transistor from a bottom of the substrate 110 to thereby minimize leakage current. For example, the light blocking layer LS may block light incident on a second active layer ACT2 of the second transistor T2, which is a driving transistor.

The storage capacitor Cst is disposed on the substrate 110 in each of the plurality of sub-pixels SP. The storage capacitor Cst may be disposed in the first area A1. The storage capacitor Cst may be disposed between the second transistor T2, and the first transistor T1 and the third transistor T3 in a plan view as shown in FIG. 2, but a location of the storage capacitor Cst is not limited thereto.

The storage capacitor Cst may include the first capacitor electrode SC1, a second capacitor electrode SC2, and a third capacitor electrode SC3.

The first capacitor electrode SC1 is disposed on the substrate 110. The first capacitor electrode SC1 may form the storage capacitor Cst together with other capacitor electrodes. The first capacitor electrode SC1 may be formed integrally with the light blocking layer LS.

The buffer layer 111 is disposed on the high-potential power supply lines VDD, the plurality of data lines DL, the reference line RL, the light blocking layer LS, and the first capacitor electrode SC1. The buffer layer 111 may reduce penetration of moisture or impurities through the substrate 110. The buffer layer 111 may be composed of, for example, a single layer or a multiple layer of silicon oxide (SiOx) or silicon nitride (SiNx), but is not limited thereto. However, the buffer layer 111 may be omitted depending on a type of the substrate 110 or a type of the transistor, but is not limited thereto.

First, the first transistor T1 is disposed on the buffer layer 111 in each of the plurality of sub-pixels SP. The first transistor T1 may be disposed in the first area A1.

The first transistor T1 is a transistor that transmits the data voltage Vdata to a second gate electrode GE2 of the second transistor T2. The first transistor T1 may be turned on by a scan signal from the scan line SL, and the data voltage Vdata from the data line DL may be transmitted to the second gate electrode GE2 of the second transistor T2 through the first transistor T1 that is turned-on. Accordingly, the first transistor T1 may be referred to as a switching transistor.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be formed of a semiconductor material such as an oxide semiconductor, amorphous silicon, and polysilicon, but is not limited thereto.

The gate insulating layer 112 is disposed on the first active layer ACT1. The gate insulating layer 112 is an insulating layer for insulating the first active layer ACT1 and the first gate electrode GE1, and may be composed of a single layer or multiple layers of silicon oxide (SiOx) or silicon nitride (SiNx), but is not limited thereto.

The first gate electrode GE1 is disposed on the gate insulating layer 112. The first gate electrode GE1 may be electrically connected to the scan line SL. The first gate electrode GE1 may be formed of a conductive material, such as copper (Cu), aluminum (Al), molybdenum (Mo), nickel (Ni), titanium (Ti), and chromium (Cr), or an alloy thereof, but is not limited thereto.

The interlayer insulating layer 113 is disposed on the first gate electrode GE1. Contact holes are formed in the interlayer insulating layer 113 to connect the first source electrode SE1 and the first drain electrode DE1 to the first active layer ACT1. The interlayer insulating layer 113 is an insulating layer to protect components under the interlayer insulating layer 113, and may be composed of a single layer or multiple layers of silicon oxide (SiOx) or silicon nitride (SiNx), but is not limited thereto.

The first source electrode SE1 and the first drain electrode DE1 that are electrically connected to the first active layer ACT1 are disposed on the interlayer insulating layer 113. The first drain electrode DE1 may be connected to the data line DL and the first active layer ACT1, and the first source electrode SE1 may be connected to the first active layer ACT1 and the second gate electrode GE2 of the second transistor T2. The first source electrode SE1 and the first drain electrode DE1 may be formed of a conductive material, for example, copper (Cu), aluminum (Al), molybdenum (Mo), nickel (Ni), titanium (Ti), chromium (Cr) or an alloy thereof, but the present disclosure is not limited thereto.

The second transistor T2 is disposed on the buffer layer 111 in each of the plurality of sub-pixels SP. The second transistor T2 may be disposed in the first area A1.

The second transistor T2 is a transistor that supplies a driving current to the light emitting element LED. The second transistor T2 is turned on and may control the driving current flowing to the light emitting element LED. Accordingly, the second transistor T2 that controls the driving current may be referred to as a driving transistor.

The second transistor T2 includes the second active layer ACT2, the second gate electrode GE2, a second source electrode SE2, and a second drain electrode DE2.

The second active layer ACT2 is disposed on the buffer layer 111. The second active layer ACT2 may be formed of a semiconductor material such as an oxide semiconductor, amorphous silicon, and polysilicon, but is not limited thereto.

The gate insulating layer 112 is disposed on the second active layer ACT2, and the second gate electrode GE2 is disposed on the gate insulating layer 112. The second gate electrode GE2 may be electrically connected to the first source electrode SE1 of the first transistor T1. The second gate electrode GE2 may be formed of a conductive material, such as copper (Cu), aluminum (Al), molybdenum (Mo), nickel (Ni), titanium (Ti), and chromium (Cr), or an alloy thereof, but is not limited thereto.

The interlayer insulating layer 113 is disposed on the second gate electrode GE2, and the second source electrode SE2 and the second drain electrode DE2 that are electrically connected to the second active layer ACT2 are disposed on the interlayer insulating layer 113. The second drain electrode DE2 may be electrically connected to the second active layer ACT2 and the high-potential power supply line VDD, and the second source electrode SE2 may be electrically connected to the second active layer ACT2 and the light emitting element LED. The second source electrode SE2 and the second drain electrode DE2 may be formed of a conductive material, such as copper (Cu), aluminum (Al), molybdenum (Mo), nickel (Ni), titanium (Ti), and chromium (Cr) or an alloy thereof, but are not limited thereto.

The third transistor T3 is disposed on the buffer layer 111 in each of the plurality of sub-pixels SP. The third transistor T3 may be disposed in the first area A1.

The third transistor T3 is a transistor for compensating a threshold voltage of the second transistor T2. The third transistor T3 is connected between the second source electrode SE2 of the second transistor T2 and the reference line RL. The third transistor T3 is turned on and may transmit a reference voltage to the second source electrode SE2 of the second transistor T2 and sense the threshold voltage of the second transistor T2. Accordingly, the third transistor T3, which senses characteristics of the second transistor T2, may be referred to as a sensing transistor.

The third transistor T3 includes a third active layer ACT3, a third gate electrode GE3, a third source electrode SE3, and the third drain electrode DE3.

The third active layer ACT3 is disposed on the buffer layer 111. The third active layer ACT3 may be formed of a semiconductor material such as an oxide semiconductor, amorphous silicon, and polysilicon, but is not limited thereto.

The gate insulating layer 112 is disposed on the third active layer ACT3, and the third gate electrode GE3 is disposed on the gate insulating layer 112. The third gate electrode GE3 may be electrically connected to the scan line SL. The third gate electrode GE3 may be formed of a conductive material, such as copper (Cu), aluminum (Al), molybdenum (Mo), nickel (Ni), titanium (Ti), and chromium (Cr), or an alloy thereof, but is not limited thereto.

The interlayer insulating layer 113 is disposed on the third gate electrode GE3, and the third source electrode SE3 and the third drain electrode DE3 that are electrically connected to the third active layer ACT3 are disposed on the interlayer insulating layer 113. The third drain electrode DE3 may be electrically connected to the third active layer ACT3 and the reference line RL, and the third source electrode SE3 may be electrically connected to the third active layer ACT3 and the second source electrode SE2 of the second transistor T2. The third source electrode SE3 and the third drain electrode DE3 may be formed of a conductive material, such as copper (Cu), aluminum (Al), molybdenum (Mo), nickel (Ni), titanium (Ti), and chromium (Cr) or an alloy thereof, but is not limited thereto.

The first transistor T1 and the third transistor T3 shown in FIG. 2 are transistors that are all controlled by being connected to the scan line SL, but are not limited thereto, and the pixel circuit may include transistors connected to emission lines EL.

The second capacitor electrode SC2 is disposed on the gate insulating layer 112. The second capacitor electrode SC2 is one of electrodes forming the storage capacitor Cst, and may be disposed to overlap the first capacitor electrode SC1. The second capacitor electrode SC2 may be formed integrally with the second gate electrode GE2 of the second transistor T2 and may be electrically connected to the second gate electrode GE2. The first capacitor electrode SC1 and the second capacitor electrode SC2 may be disposed to be spaced apart from each other with the buffer layer 111 and the gate insulating layer 112 interposed therebetween.

In addition, the plurality of scan lines SL, the auxiliary high-potential power supply line VDDA, and the third capacitor electrode SC3 are disposed on the interlayer insulating layer 113.

First, the scan line SL is a line that transmits the scan signal SCAN to each of the plurality of sub-pixels SP. The scan line SL may extend in the row direction across the plurality of sub-pixels SP. The scan line SL may be electrically connected to the first gate electrode GE1 of the first transistor T1 and the third gate electrode GE3 of the third transistor T3 of each of the plurality of sub-pixels SP.

The auxiliary high-potential power supply line VDDA is disposed on the interlayer insulating layer 113. The auxiliary high-potential power supply line VDDA may extend in the row direction and be disposed across the plurality of sub-pixels SP. For example, the auxiliary high-potential power supply line VDDA may be disposed between the first area A1 and the second area A2 as shown in FIG. 2, but is not limited thereto.

The auxiliary high-potential power supply line VDDA may be electrically connected to the high-potential power supply line VDD extending in the column direction and the second drain electrode DE2 of the second transistor T2 of each of the plurality of sub-pixels SP disposed in the row direction.

The third capacitor electrode SC3 is disposed on the interlayer insulating layer 113. The third capacitor electrode SC3 is an electrode that forms the storage capacitor Cst, and may be disposed to overlap the first capacitor electrode SC1 and the second capacitor electrode SC2. The third capacitor electrode SC3 may be formed integrally with the second source electrode SE2 of the second transistor T2 and may be electrically connected to the second source electrode SE2. In addition, the second source electrode SE2 may be electrically connected to the first capacitor electrode SC1 through contact holes formed in the interlayer insulating layer 113 and the buffer layer 111. Accordingly, the first capacitor electrode SC1 and the third capacitor electrode SC3 may be electrically connected to the second source electrode SE2 of the second transistor T2.

The storage capacitor Cst may store a potential difference between the second gate electrode GE2 and the second source electrode SE2 of the second transistor T2 while the light emitting element LED emits light, and may supply a constant current to the light emitting element LED. The storage capacitor Cst includes the first capacitor electrode SC1 that is formed on the substrate 110 and connected to the second source electrode SE2, the second capacitor electrode SC2 that is formed on the buffer layer 111 and the gate insulating layer 112 and connected to the second gate electrode GE2, and the third capacitor electrode SC3 that is formed on the interlayer insulating layer 113 and connected to the second source electrode SE2. Accordingly, the storage capacitor Cst may store a voltage between the second gate electrode GE2 and the second source electrode SE2 of the second transistor T2.

The first passivation layer 114 is disposed on the first transistor T1, the second transistor T2, the third transistor T3, and the storage capacitor Cst. The first passivation layer 114 is an insulating layer to protect components under the first passivation layer 114, and may be composed of a single layer or multiple layers of silicon oxide (SiOx) or silicon nitride (SiNx), but is limited thereto.

The first planarization layer 115 is disposed on the first passivation layer 114. The first planarization layer 115 may planarize an upper portion of the substrate 110 on which the plurality of transistors T1, T2, and T3 and the storage capacitor Cst are disposed. The first planarization layer 115 may be composed of a single layer or a multilayer, and may be formed of, for example, photoresist or an acryl-based organic material, but is not limited thereto.

The second passivation layer 116 is disposed on the first planarization layer 115. The second passivation layer 116 is an insulating layer to protect components under the second passivation layer 116, and may be composed of a single layer or multiple layers of silicon oxide (SiOx) or silicon nitride (SiNx), but is limited thereto.

A connection electrode 150 and a plurality of the assembly lines 120 are disposed on the second passivation layer 116.

The connection electrode 150 is an electrode that electrically connects the second transistor T2 and pixel electrodes PE. The connection electrode 150 may be electrically connected to the second source electrode SE2 and the third capacitor electrode SC3 through contact holes formed in the second passivation layer 116, the first planarization layer 115, and the first passivation layer 114.

The connection electrode 150 may have a multilayer structure having a first connection layer 150a and a second connection layer 150b. The first connection layer 150a is disposed on the second passivation layer 116, and the second connection layer 150b is disposed to cover the first connection layer 150a. The second connection layer 150b may be disposed to surround both an upper surface and side surfaces of the first connection layer 150a.

The second connection layer 150b is formed of a material that is more resistant to corrosion than the first connection layer 150a. Thus, when manufacturing the display device 100, short-circuit defects occurring due to migration between the first connection layer 150a and adjacent lines may be minimized. For example, the first connection layer 150a may be formed of a conductive material such as copper (Cu) and chromium (Cr), and the second connection layer 150b may be formed of molybdenum (Mo), molybdenum titanium (MoTi), or the like. However, the present disclosure is not limited thereto.

The plurality of assembly lines 120 are disposed on the second passivation layer 116.

The plurality of assembly lines 120 includes a plurality of first assembly lines 121 and a plurality of second assembly lines 122.

The plurality of first assembly lines 121 and the plurality of second assembly lines 122 extend in the column direction in each of the first sub-pixel SP1, the second sub-pixel SP2, and the third sub-pixel SP3, and may be disposed to be spaced apart from each other at regular intervals. For example, the first assembly line 121 and the second assembly line 122 may be disposed to be spaced apart from each other in the first area A1 with the plurality of transistors T1, T2, and T3 therebetween.

The plurality of assembly lines 120 may be electrically connected to the low-potential power supply lines and receive low-voltage power. That is, the plurality of assembly lines 120 may be referred to as the low-potential power supply lines, and the low-potential power supply lines may extend in the column direction in each of the plurality of sub-pixels SP. For example, the low-potential power supply lines may be disposed in each of the first sub-pixel SP1, the second sub-pixel SP2, and the third sub-pixel SP3, but are not limited thereto.

Each of the plurality of assembly lines 120 includes conductive layers 121a and 122a disposed on the second passivation layer 116, and clad layers 121b and 122b disposed on the conductive layers 121a and 122a and covering upper surfaces and side surfaces of the conductive layers 121a and 122a.

The first assembly line 121 includes a first conductive layer 121a and a first clad layer 121b, and the second assembly line 122 includes a second conductive layer 122a and a second clad layer 122b.

The first conductive layer 121a and the second conductive layer 122a may not overlap the light emitting element LED. That is, ends of the first conductive layer 121a and the second conductive layer 122a may be disposed outside an end of the light emitting element LED.

The first clad layer 121b of the first assembly line 121 may be disposed to cover an upper surface and side surfaces of the first conductive layer 121a, and the second clad layer 122b of the second assembly line 122 may be disposed to cover an upper surface and side surfaces of the second conductive layer 122a.

The first assembly line 121 and the second assembly line 122 may include a protrusion protruding toward the light emitting element LED. For example, the protrusion of the first assembly line 121 may be the first clad layer 121b extending toward a center of the light emitting element LED among the first conductive layer 121a and the first clad layer 121b. The protrusion of the second assembly line 122 may be the second clad layer 122b extending toward the center of the light emitting element LED among the second conductive layer 122a and the second clad layer 122b of the second assembly line 122. In this case, each of the protrusion of the first assembly line 121 and the protrusion of the second assembly line 122 may be disposed to overlap an area corresponding to less than half of an area of a lower surface of the light emitting element LED.

The conductive layers 121a and 122a may be formed of the same material through the same process as the first connection layer 150a of the connection electrode 150. For example, the conductive layers 121a and 122a may be formed of a conductive material such as copper (Cu) and chromium (Cr). Additionally, the clad layers 121b and 122b may be formed of the same material through the same process as the second connection layer 150b of the connection electrode 150. For example, the clad layer 122b may be formed of a material that is more resistant to corrosion than the conductive layers 121a and 122a, such as molybdenum (Mo) and molybdenum titanium (MoTi), but is not limited thereto.

The third passivation layer 117 is disposed on the connection electrode 150 and the assembly lines 120. The third passivation layer 117 is an insulating layer to protect components under the third passivation layer 117, and may be composed of a single layer or multiple layers of silicon oxide (SiOx) or silicon nitride (SiNx), but is limited thereto.

Some regions of the third passivation layer 117 may be open in areas adjacent to a plurality of the light emitting elements LED. For example, the third passivation layer 117 may expose portions of upper surfaces of the first assembly line 121 and the second assembly line 122 in areas adjacent to both sides of the plurality of light emitting elements LED.

The plurality of light emitting elements LED are disposed on the third passivation layer 117. Referring to FIG. 3, the lower surface of the light emitting element LED is disposed to overlap the first assembly line 121 and the second assembly line 122.

As shown in FIG. 2, two light emitting elements LED may be disposed in one sub-pixel SP. The light emitting element LED is an element that emits light by electric current. The light emitting elements LED may include light emitting elements LED that emit red light, green light, blue light, and the like, and a combination of these light emitting elements may implement light of various colors, including white. Additionally, light of various colors may be realized by using a light emitting element LED that emits light of a specific color and a light conversion member that converts light from the light emitting element LED into light of a different color.

The light emitting elements LED may emit light by receiving a driving current from the second transistor T2. The light emitting elements LED may include a red light emitting element, a green light emitting element, and a blue light emitting element. For example, the light emitting element LED disposed in the first sub-pixel SP1 may be a red light emitting element, the light emitting element LED disposed in the second sub-pixel SP2 may be a green light emitting element, and the light emitting element LED disposed in the third sub-pixel SP3 may be a blue light emitting element, but the present disclosure is not limited thereto.

In this case, the plurality of light emitting elements LED disposed in one sub-pixel SP may be connected in parallel. That is, one electrode of each of the plurality of light emitting elements LED may be connected to the source electrode SE2 of the same second transistor T2, and the other electrode thereof may be connected to the same assembly line 120.

The light emitting element LED may include a first light emitting element 130 and a second light emitting element 140. The light emitting elements LED disposed in each of the plurality of sub-pixels SP may be disposed in the column direction. For example, as shown in FIG. 2, the second light emitting element 140 may be disposed above the first light emitting element 130.

The first light emitting element 130 may emit light of the same color as the second light emitting element 140. In this case, since the first light emitting element 130 and the second light emitting element 140 are the same type of light emitting elements LED, a size of the first light emitting element 130 may be the same as a size of the second light emitting element 140. Here, the size of the light emitting element LED may mean the area of the lower surface of the light emitting element LED, a width, a volume, and a height in a cross-section thereof, and the like, but the present disclosure is not limited thereto.

In FIGS. 2 and 3, for convenience of explanation, it is illustrated that two light emitting elements LED are disposed in each of the plurality of sub-pixels SP. However, the number of the light emitting elements LED disposed in each of the plurality of sub-pixels SP is not limited thereto.

Referring to FIG. 3, the light emitting element 130 includes a first semiconductor layer 131, a light emitting layer 132, a second semiconductor layer 133, a first electrode 134, a second electrode 135, and an encapsulation layer 136.

The first semiconductor layer 131 is disposed on the third passivation layer 117, and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers in which materials such as gallium nitride (GaN), indium aluminum phosphide (InAlP), and gallium arsenide (GaAs) are doped with p-type or n-type impurities. The p-type impurities may be magnesium (Mg), zinc (Zn), beryllium (Be), and the like, and the n-type impurities may be silicon (Si), germanium (Ge), tin (Sn), and the like, but the present disclosure is not limited thereto.

A portion of the first semiconductor layer 131 may be disposed to protrude outside the second semiconductor layer 133. An upper surface of the first semiconductor layer 131 may be composed of a portion that overlaps a lower surface of the second semiconductor layer 133 and a portion that is disposed outside the lower surface of the second semiconductor layer 133. However, sizes and shapes of the first semiconductor layer 131 and the second semiconductor layer 133 may be changed in various ways, but are not limited thereto.

The light emitting layer 132 is disposed between the first semiconductor layer 131 and the second semiconductor layer 133. The light emitting layer 132 may emit light by receiving holes and electrons from the first semiconductor layer 131 and the second semiconductor layer 133. The light emitting layer 132 may be formed of a single- or multi-quantum well (MQW) structure, and may be formed of, for example, indium gallium nitride (InGaN) or gallium nitride (GaN), but is not limited thereto.

The first electrode 134 is disposed to surround a lower surface and side surfaces of the first semiconductor layer 131. The first electrode 134 is an electrode for electrically connecting the first light emitting element 130 and the assembly line 120. The first electrode 134 may be formed of a conductive material, for example, a transparent conductive material such as indium tin oxide (ITO) and indium zinc oxide (IZO), or an opaque conductive material such as titanium (Ti), gold (Au), silver (Ag), and copper (Cu) or an alloy thereof, but is not limited thereto.

The second electrode 135 is disposed on the upper surface of the second semiconductor layer 133. The second electrode 135 is an electrode that electrically connects the second semiconductor layer 133 and the pixel electrode PE, which will be described later. The second electrode 135 may be formed of a conductive material, for example, a transparent conductive material such as indium tin oxide (ITO) and indium zinc oxide (IZO), but is not limited thereto.

The encapsulation layer 136 surrounding at least a portion of the first semiconductor layer 131, the light emitting layer 132, the second semiconductor layer 133, the first electrode 134, and the second electrode 135 is disposed. The encapsulation layer 136 is formed of an insulating material and may protect the first semiconductor layer 131, the light emitting layer 132, and the second semiconductor layer 133. The encapsulation layer 136 may be disposed to cover the light emitting layer 132, a portion of a side surface of the first semiconductor layer 131 adjacent to the light emitting layer 132, and a portion of a side surface of the second semiconductor layer 133 adjacent to the light emitting layer 132. The first electrode 134 and the second electrode 135 may be exposed from the encapsulation layer 136, and the contact electrode CE and pixel electrode PE and the first electrode 134 and the second electrode 135 to be formed later may be electrically connected.

An adhesive layer AD may be disposed between the plurality of light emitting elements LED, and the third passivation layer 117 and the assembly line 120. The adhesive layer AD may be an organic film that temporarily fixes the light emitting element LED during a self-assembly process of the light emitting element LED. In manufacturing the display device 100, when an organic film covering the light emitting element LED is formed, a portion of the organic film fills a space between the light emitting element LED, and the third passivation layer 117 and the assembly line 120, so that the light emitting element LED may be temporarily fixed onto the third passivation layer 117 and the assembly line 120. Thereafter, even if the organic film is removed, a portion of the organic film that has permeated into a lower portion of the light emitting element LED may remain without being removed and become an adhesive layer. The adhesive layer AD may be formed of an organic material, for example, photoresist or an acryl-based organic material, but is not limited thereto.

The contact electrode CE is disposed on a side surface of the light emitting element LED. The contact electrode CE is an electrode for electrically connecting the light emitting element LED and the assembly line 120. The contact electrode CE may be disposed to surround at least a portion of the first semiconductor layer 131 and the first electrode 134 of the light emitting element LED in an area overlapping the first assembly line 121 and the second assembly line 122. In this case, the contact electrode CE may be electrically connected to the first assembly line 121 and the second assembly line 122 exposed by the third passivation layer 117 in the open area of the third passivation layer 117.

Meanwhile, the contact electrode CE may be formed of a conductive material, for example, copper (Cu), aluminum (Al), molybdenum (Mo), nickel (Ni), titanium (Ti), chromium (Cr), or an alloy thereof.

The second planarization layer 118 is disposed on the light emitting element LED and the contact electrode CE. The second planarization layer 118 planarizes the third passivation layer 117 and, similar to the adhesive layer AD, may fix the light emitting element LED onto the substrate 110.

The second planarization layer 118 may be composed of a single layer or a multilayer, and may be formed of, for example, an acryl-based organic material, but is not limited thereto. Meanwhile, the second planarization layer 118 includes a contact hole that exposes a portion of the upper surface of the light emitting element LED. The pixel electrode PE may be disposed in the contact hole of the second planarization layer 118 and electrically connected to the second electrodes 135 of the plurality of light emitting elements LED.

The pixel electrode PE is disposed on the second planarization layer 118.

The pixel electrode PE is an electrode for electrically connecting the plurality of light emitting elements LED and the connection electrode 150. The pixel electrode PE is electrically connected to the pixel circuit, and may also be electrically connected to the first light emitting element 130 and the second light emitting element 140. That is, the pixel electrode PE may be connected to the first light emitting element 130 and the second light emitting element 140 in the second area A2, and may be electrically connected to the second transistor T2 in the first area A1. In this case, the pixel electrode PE may be disposed to overlap the second active layer ACT2 of the second transistor T2 in the first area A1, and through the contact hole formed in the second planarization layer 118, the pixel electrode PE may be electrically connected to the connection electrode 150 and the second transistor T2.

The pixel electrode PE may be formed of a conductive material, for example, a transparent conductive material such as indium tin oxide (ITO) and indium zinc oxide (IZO), but is not limited thereto.

Referring to FIG. 2 and FIG. 3, the first light emitting element 130 and the second light emitting element 140 is disposed on the third passivation layer 117. The second light emitting element 140 is disposed above the first light emitting element 130 and is disposed together with the first light emitting element 130 and the pixel circuit in one sub-pixel SP.

The second light emitting element 140 includes a first semiconductor layer, a light emitting layer, a second semiconductor layer, a first electrode, a second electrode, and an encapsulation layer. The first semiconductor layer, the light emitting layer, the second semiconductor layer, the second electrode, and the encapsulation layer of the second light emitting element 140 may be substantially the same as the first semiconductor layer 131, the light emitting layer 132, the second semiconductor layer 133, the second electrode 135, and the encapsulation layer 136 of the first light emitting element 130. Accordingly, redundant descriptions will be omitted.

The second light emitting element 140 may be electrically connected to the first light emitting element 130 and the pixel electrode PE extending from the pixel circuit through a contact hole formed in the second planarization layer 118. Accordingly, in one sub-pixel SP, the first light emitting element 130 and the second light emitting element 140 may be electrically connected to the second transistor T2.

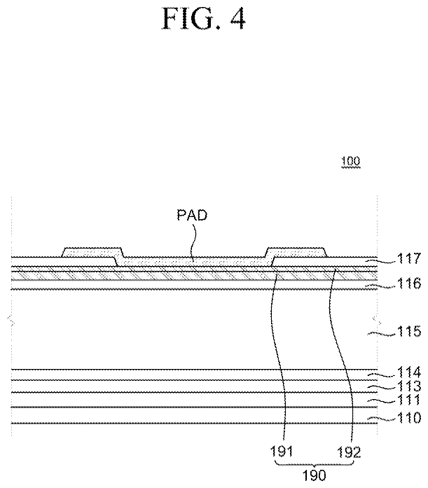

Hereinafter, a pad area will be described with reference to FIG. 4.

FIG. 4 is a cross-sectional view of the pad area of the display device according to an exemplary aspect of the present disclosure. In FIG. 4, for convenience of illustration, only the substrate 110, the buffer layer 111, the interlayer insulating layer 113, the first passivation layer 114, the first planarization layer 115, the second passivation layer 116, the third passivation layer 117, link lines 190, and a pad electrode PAD are shown.

The pad area may be disposed in an outer area of the display device 100 at one end of the display device 100, but is not limited thereto.

First, referring to FIG. 4, the link lines 190 and the pad electrode PAD are disposed on the second passivation layer 116 in the pad area.

The link lines 190 may connect the pad electrode PAD and the plurality of sub-pixels SP. For example, the pad electrode PAD may be connected to a plurality of signal lines, such as the gate lines GL, the data lines DL, the high-potential power supply lines VDD, sensing lines SL, and the reference line RL that are connected to the plurality of sub-pixels SP, and a signal that is applied to the pad electrode PAD may be transmitted to the plurality of signal lines through the link lines 190.

The link lines 190 may be formed of the same materials as various conductive materials disposed in the display area AA. For example, the link lines 190 may be formed of the same material as the assembly lines 120. Accordingly, the link lines 190 may be formed of the same material as the conductive layers 121a and 122a and the clad layers 121b and 122b. Accordingly, the link lines 190 may be formed of a first link line 191 formed of the same material as the conductive layers 121a and 122a, and a second link line 192 formed of the same material as the clad layers 121b and 122b, but the present disclosure is not limited thereto. Additionally, the link lines 190 may be formed integrally with the pad electrode PAD or may be configured separately.

The third passivation layer 117 is disposed on the link lines 190. The third passivation layer 117 may open a portion of the link lines 190. Accordingly, the third passivation layer 117 may expose a portion of an upper surface of the link lines 190.

The pad electrode PAD is disposed on the third passivation layer 117. The pad electrode PAD may be electrically connected to the link lines 190 in the open area of the third passivation layer 117.

The pad electrode PAD may be disposed at one end of the substrate 110 and connected to a driving IC, such as a gate driver IC and a data driver IC, disposed to supply signals to the plurality of sub-pixels SP. For example, the pad electrode PAD may be electrically connected to a plurality of flexible films and a printed circuit board on which the driving IC is disposed, but is not limited thereto.

The pad electrode PAD may be formed of the same material as various conductors disposed in the display area AA. For example, the pad electrode PAD may be formed of the same material as the pixel electrode PE on the link lines 190, but is not limited thereto.

In general, when a display device is manufactured by self-assembling a light emitting element inside an opening, the light emitting element is assembled on a planarization layer that planarizes upper portions of a plurality of transistors and a plurality of lines. Specifically, the light emitting element may be disposed inside a display panel through an alternating current voltage applied to an assembly line that is formed on the planarization layer.

Meanwhile, when an alternating current voltage is applied to the assembly line to assemble the light emitting element, an electric field formed in the assembly line may also affect a plurality of transistors. Accordingly, when the plurality of transistors are disposed adjacent to the assembly line, the plurality of transistors may be damaged by an electric field formed in the assembly line. In particular, when the light emitting element is a small light emitting element such as a micro-LED, a relatively high current is applied to the assembly line to improve assembly efficiency. Accordingly, as a size of the light emitting element decreases, the electric field formed in the assembly line increases, causing a defect in which damage to the plurality of transistors may become more severe.

Accordingly, in the display device 100 according to an exemplary aspect of the present disclosure, a plurality of the transistors T1, T2, and T3 and the assembly lines 120 are disposed to be spaced apart from each other. First, the assembly lines 120 may be disposed to be spaced apart from the plurality of transistors T1, T2, and T3 in the first area A1. For example, the plurality of transistors T1, T2, and T3 may be disposed in a center of each of the plurality of sub-pixels SP, and the first assembly line 121 and the second assembly line 122 may be disposed outside the transistors T1, T2, and T3 in the first area A1. Additionally, the light emitting element LED is disposed in the second area A2 separated from the first area A1. Accordingly, even if the assembly lines 120 include a protrusion toward the light emitting element LED in the second area A2, the assembly lines 120 may not overlap the plurality of transistors T1, T2, and T3 and may be disposed to be spaced apart from the transistors T1, T2, and T3. Accordingly, an influence of a magnetic field formed on the assembly line 120 when assembling the light emitting element LED on the plurality of transistors T1, T2, and T3 may be minimized.

Meanwhile, in existing display devices, low-potential power is applied to each of sub-pixels through a common line. Accordingly, a voltage drop phenomenon may occur in the common line to which low-potential power is applied, resulting in luminance deviation depending on areas. Accordingly, a driving voltage and power consumption increase, causing a defect in which luminance of the display device may become uneven.

Accordingly, in the display device 100 according to an exemplary aspect of the present disclosure, low-potential power is applied to the plurality of assembly lines 120. Accordingly, low-potential power may be applied to each of the plurality of sub-pixels SP through the first assembly line 121 and the second assembly line 122 disposed to be spaced apart from each other, thereby minimizing voltage drop, and power consumption is reduced and limitations with uneven luminance of the display device 100 may be prevented.

Meanwhile, in the display device 100 according to an exemplary aspect of the present disclosure, the link lines 190 formed of the same material as the assembly lines 120 may be used and a plurality of inorganic layers disposed below the link lines 190 and a planarization layer may not be removed. Accordingly, a step difference between the pad electrode PAD and the link lines 190 may be reduced. In addition, the link lines 190 is composed of a multilayer including the first link line 191 formed of the same material as the conductive layers 121a and 122a of the assembly line 120, and the second link line 192 formed of the same material as the clad layers 121b and 122b, and thus, may reduce damage to the pad electrode PAD and defects thereof caused by impacts and loss of the link lines 190.

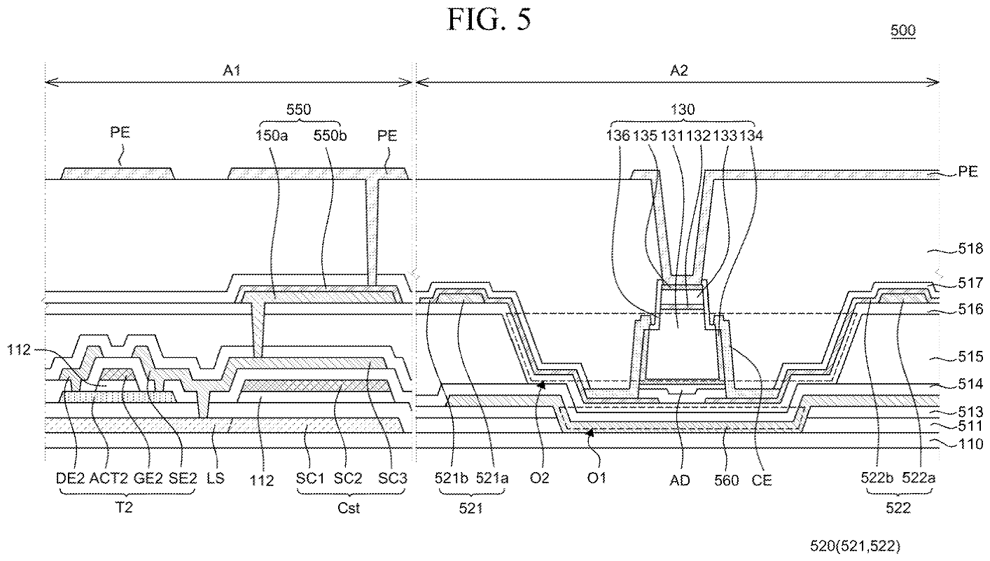

FIG. 5 is a cross-sectional view of a display device according to another exemplary aspect of the present disclosure. Other configurations of a display device 500 of FIG. 5 are substantially identical to those of the display device 100 of FIGS. 1 to 4, except for differences in a buffer layer 511, an interlayer insulating layer 513, a first passivation layer 514, a first planarization layer 515, a second passivation layer 516, a third passivation layer 517, a second planarization layer 518, and assembly lines 520, and an addition of a reflective layer 560. Thus, duplicate descriptions will be omitted.

Referring to FIG. 5, the buffer layer 511 and the interlayer insulating layer 513 are disposed on the substrate 110. The buffer layer 511 and the interlayer insulating layer 513 are disposed in the first area A1 and the second area A2.

Meanwhile, the buffer layer 511 and the interlayer insulating layer 513 may include a first opening O1 disposed in an area overlapping the second area A2. The buffer layer 511 and the interlayer insulating layer 513 may each be an inorganic layer. The first opening O1 is an area where the buffer layer 511 and the interlayer insulating layer 513 are removed, and may be disposed in an area overlapping with the light emitting element LED.

The reflective layer 560 is disposed on the buffer layer 511 and the interlayer insulating layer 513 in each of the plurality of sub-pixels SP. The reflective layer 560 may be disposed to overlap the light emitting element LED in the second area A2.

The reflective layer 560 is disposed in the first opening O1 and may be disposed to extend outwardly of the first opening O1. For example, the reflective layer 560 is disposed in a cup structure along a shape of the first opening O1 as shown in FIG. 5, and may cover the buffer layer 511, a side surface of the interlayer insulating layer 513, and an upper surface of the interlayer insulating layer 513 at the outside of the first opening O1. Accordingly, the reflective layer 560 may reflect light emitted from the light emitting element LED upwardly of the substrate 110. For example, the reflective layer 560 may reflect light traveling from the light emitting element LED toward a bottom or a side surface of the substrate 110, upwardly of the substrate 110.

The reflective layer 560 may be formed of the same material as the source electrode or drain electrode of the plurality of transistors T1, T2, and T3. For example, the reflective layer 560 may be formed of a conductive material, such as copper (Cu), aluminum (Al), molybdenum (Mo), nickel (Ni), titanium (Ti), and chromium (Cr), or an alloy thereof, but is not limited thereto.

The first passivation layer 514 is disposed on the interlayer insulating layer 513 and the reflective layer 560. The first passivation layer 514 may be disposed along a shape of the first opening O1 in the second area A2. Accordingly, the first passivation layer 514 may be disposed in a cup structure.

The first planarization layer 515 is disposed on the first passivation layer 514. The first planarization layer 515 may include a second opening O2 disposed in an area overlapping the second area A2. The second opening O2 is an area where the first planarization layer 515 has been removed, and may be disposed in an area overlapping with the light emitting element LED. That is, the first planarization layer 515 may surround the light emitting element LED in the area where the second opening O2 is disposed.

The second opening O2 may be disposed to overlap the first opening O1, and the second opening O2 may be disposed to have a larger area than the first opening O1. For example, an end of the first planarization layer 515 may be disposed on the first passivation layer 514 as shown in FIG. 5.

The second passivation layer 516 is disposed on the first passivation layer 514 and the first planarization layer 515. The second passivation layer 516 may be disposed to be in contact with the first passivation layer 514 in the second opening O2. Accordingly, the second passivation layer 516 may be disposed in a cup structure along shapes of the first opening O1 and the second opening O2 in the second area A2, and may be disposed with a step between the first opening O1 and the second opening O2.

A connection electrode 550 and a plurality of the assembly lines 520 are disposed on the second passivation layer 516.

The connection electrode 550 may include the first connection layer 150a and the second connection layer 550b covering the first connection layer 150a.

The connection electrode 550 may be formed of a transparent conductive material. For example, the second connection layer 550b of the connection electrode 550 may be formed of a transparent conductive material such as indium tin oxide (ITO) and indium zinc oxide (IZO), but is not limited thereto.

The plurality of assembly lines 520 may be disposed in the first opening O1 and the second opening O2. That is, the plurality of assembly lines 520 may be disposed in a cup structure along the shapes of the first opening O1 and the second opening O2 in the second area A2, and may be disposed with a step between the first opening O1 and the second opening O2.

The plurality of assembly lines 520 are disposed on the second passivation layer 516.

The plurality of assembly lines 520 includes a plurality of first assembly lines 521 and a plurality of second assembly lines 522.

The first assembly line 521 includes a first conductive layer 121a and a first clad layer 521b, and the second assembly line 522 includes a second conductive layer 122a and a second clad layer 522b.

The conductive layers 121a and 122a are disposed on the second passivation layer 516, and the clad layers 521b and 522b are disposed on the conductive layers 121a and 122a and may cover all of upper surfaces and side surfaces of the conductive layers 121a and 122a.

The conductive layers 521a and 522a may not overlap the light emitting element LED. That is, ends of the conductive layers 521a and 522a may be disposed outside the end of the light emitting element LED. For example, the conductive layers 521a and 522a may be disposed in an area that overlaps the first planarization layer 515 outside the second opening O2.

The clad layers 521b and 522b are disposed to cover the upper surfaces and side surfaces of the conductive layers 521a and 522a, and the clad layers 521b and 522b may be disposed in the first opening O1 and the second opening O2 and may be disposed to overlap the light emitting element LED.

Portions of the first assembly line 521 and the second assembly line 522 disposed in the first opening O1 and the second opening O2 may be formed of a transparent conductive material. For example, the first clad layer 521b and the second clad layer 522b of the first assembly line 521 and the second assembly line 522 may be formed of a transparent conductive material such as indium tin oxide (ITO) and indium zinc oxide (IZO), but is not limited thereto.

The third passivation layer 517 is disposed on the assembly line 520.

A plurality of light emitting elements LED are disposed on the third passivation layer 517. Referring to FIG. 5, the light emitting element LED is disposed in an area overlapping the first opening O1 and the second opening O2. Accordingly, the light emitting element LED may be surrounded by the buffer layer 511, the interlayer insulating layer 513, and the first planarization layer 515 disposed outside the first opening O1 and the second opening O2.

The light emitting element LED may include the first light emitting element 130 and the second light emitting element 140. Since the first light emitting element 130 and the second light emitting element 140 have substantially the same configuration, only the first light emitting element 130 will be described below for convenience of explanation.

The first light emitting element 130 includes the first semiconductor layer 131, the light emitting layer 132, the second semiconductor layer 133, the first electrode 134, the second electrode 135, and the encapsulation layer 136.

The contact electrode CE is disposed on the side surface of the first light emitting element 130. For example, as shown in FIG. 5, the contact electrode CE may be disposed to surround at least a portion of the first electrode 134 and the first semiconductor layer 131 of the first light emitting element 130 in an area overlapping the first opening O1 and the second opening O2, and may be electrically connected to the first assembly line 521 and the second assembly line 522 that are exposed by the third passivation layer 517 in an area where the third passivation layer 517 is open.

The second planarization layer 518 is disposed on the first light emitting element 130 and the contact electrode CE. The second planarization layer 518 flattens the third passivation layer 517 and the first light emitting element 130, and may fix the first light emitting element 130 onto the substrate 110, similar to the adhesive layer AD.

The second planarization layer 518 may fill the first opening O1 and the second opening O2 on the outside of the first light emitting element 130. Accordingly, an upper surface of the second planarization layer 518 may be disposed at a position higher than the upper surface of the first light emitting element 130, as shown in FIG. 5.

The pixel electrode PE is disposed on the second planarization layer 518, and a contact hole through which the pixel electrode PE and the second electrode 135 of the first light emitting element 130 may be electrically connected to each other may be disposed in the second planarization layer 518.

In the display device 500 according to another exemplary aspect of the present disclosure, the reflective layer 560 disposed on the lower surface of the light emitting element LED extends outwardly of the first opening O1 and is disposed in a cup structure. Accordingly, light emitted at a low emission angle among the light emitted from the light emitting element LED may be extracted in a front direction by the reflective layer 560 disposed on a side portion of the first opening O1. Accordingly, the reflective layer 560 formed in the first opening O1 may function like a side mirror, and a portion of light trapped inside the display device 500 may be extracted in the frontal direction of display device 500 by total reflection. Accordingly, in the display device 500 according to another exemplary aspect of the present disclosure, the reflective layer 560 prevents the light emitted from the light emitting element LED from traveling in a direction in which the plurality of transistors T1, T2, and T3 are disposed. Accordingly, light extraction efficiency of the display device 500 may be improved and power consumption may be reduced. Additionally, the influence of the plurality of transistors T1, T2, and T3 by the light emitted from the light emitting element LED may be reduced.

The exemplary aspects of the present disclosure may also be described as follows.

According to an aspect of the present disclosure, there is provided a display device. The display device includes a substrate. The substrate includes a display area in which a plurality of sub-pixels are disposed and a non-display area. The display device further includes a first assembly line and a second assembly line disposed in the plurality of sub-pixels on the substrate and spaced apart from each other. The display device further includes a light emitting element disposed on the first assembly line and the second assembly line. The display device further includes a plurality of transistors disposed in the plurality of sub-pixels. Each of the plurality of sub-pixels includes a first area in which the plurality of transistors are disposed and a second area which is separated from the first area and in which the light emitting element is disposed.

In the first area, the first assembly line and the second assembly line may be disposed to be spaced apart from each other with the plurality of transistors interposed therebetween.

The first assembly line and the second assembly line may include a protrusion protruding toward the light emitting element in the second area.

The first assembly line and the second assembly line may be connected to a low-potential power supply line to receive low-potential power.

The display device may further include a capacitor disposed in each of the plurality of sub-pixels. The capacitor is disposed in the first area.

The plurality of transistors may include a first transistor, a second transistor, and a third transistor. The capacitor is disposed between the second transistor, and the first transistor and the third transistor in a plan view.

The display device may further include a reference line, a data line, a scan line, and a high-potential power supply line connected to the plurality of sub-pixels. A source electrode of the first transistor is connected to a gate electrode of the second transistor, a drain electrode of the first transistor is connected to the data line, and a gate electrode of the first transistor is connected to the scan line. A source electrode of the second transistor is connected to the light emitting element, a gate electrode of the second transistor is connected to the source electrode of the first transistor, and a drain electrode of the second transistor is connected to the high-potential power supply line. A source electrode of the third transistor is connected to the source electrode of the second transistor, a gate electrode of the third transistor is connected to the scan line, and a drain electrode of the third transistor is connected to the reference line.

The display device may further include a light blocking layer disposed below the plurality of transistors. The capacitor includes a first capacitor electrode, a second capacitor electrode disposed on the first capacitor electrode, and a third capacitor electrode disposed on the second capacitor electrode. The first capacitor electrode is connected to the light blocking layer. The second capacitor electrode is formed of the same material as a gate electrode of the second transistor. The third capacitor electrode is connected to a source electrode or a drain electrode of the second transistor.

The display device may further include a plurality of inorganic layers disposed in the first area and the second area and having a first opening disposed therein and overlapping the light emitting element. The display device may further include a reflective layer disposed on the plurality of inorganic layers and disposed to overlap the light emitting element in the first opening.

The display device may further include a first passivation layer disposed on the plurality of inorganic layers and the reflective layer. The display device may further include a planarization layer disposed on the first passivation layer and having a second opening disposed therein and overlapping the light emitting element. The display device may further include a second passivation layer disposed on the planarization layer and the first passivation layer and in contact with the first passivation layer in the second opening.

The first assembly line and the second assembly line may be disposed on the second passivation layer and are disposed in the first opening and the second opening.

Portions of the first assembly line and the second assembly line disposed in the first opening and the second opening may be formed of a transparent conductive material.

An upper surface of the planarization layer may be disposed at a position higher than an upper surface of the light emitting element.

The reflective layer may be formed of the same material as source electrodes or drain electrodes of the plurality of transistors.

The display device may further include a high-potential power supply line disposed between the first area and the second area.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a display area in which a plurality of sub-pixels are disposed and a non-display area;
a first assembly line and a second assembly line disposed in the plurality of sub-pixels on the substrate and spaced apart from each other;
a light emitting element disposed on the first assembly line and the second assembly line; and
a plurality of transistors disposed in the plurality of sub-pixels,
wherein each of the plurality of sub-pixels includes a first area in which the plurality of transistors are disposed and a second area which is separated from the first area and in which the light emitting element is disposed.

2. The display device of claim 1, wherein, in the first area, the first assembly line and the second assembly line are disposed to be spaced apart from each other with the plurality of transistors interposed therebetween.

3. The display device of claim 2, wherein the first assembly line and the second assembly line include a protrusion protruding toward the light emitting element in the second area.

4. The display device of claim 2, wherein the first assembly line and the second assembly line are connected to a low-potential power supply line to receive low-potential power.

5. The display device of claim 1, further comprising a capacitor disposed in each of the plurality of sub-pixels,
wherein the capacitor is disposed in the first area.

6. The display device of claim 5, wherein the plurality of transistors include a first transistor, a second transistor, and a third transistor, and
wherein the capacitor is disposed between the second transistor and the first transistor in a plan view and is disposed between the second transistor and the third transistor in a plan view.

7. The display device of claim 6, further comprising a reference line, a data line, a scan line, and a high-potential power supply line connected to the plurality of sub-pixels,
wherein a source electrode of the first transistor is connected to a gate electrode of the second transistor, a drain electrode of the first transistor is connected to the data line, and a gate electrode of the first transistor is connected to the scan line,
wherein a source electrode of the second transistor is connected to the light emitting element, a gate electrode of the second transistor is connected to the source electrode of the first transistor, and a drain electrode of the second transistor is connected to the high-potential power supply line, and
wherein a source electrode of the third transistor is connected to the source electrode of the second transistor, a gate electrode of the third transistor is connected to the scan line, and a drain electrode of the third transistor is connected to the reference line.

8. The display device of claim 6, further comprising a light blocking layer disposed below the plurality of transistors,
wherein the capacitor includes a first capacitor electrode, a second capacitor electrode disposed on the first capacitor electrode, and a third capacitor electrode disposed on the second capacitor electrode,
wherein the first capacitor electrode is connected to the light blocking layer,
wherein the second capacitor electrode is formed of a same material as a gate electrode of the second transistor, and
wherein the third capacitor electrode is connected to a source electrode or a drain electrode of the second transistor.

9. The display device of claim 1, further comprising:
a plurality of inorganic layers disposed in the first area and the second area and having a first opening disposed therein and overlapping the light emitting element; and
a reflective layer disposed on the plurality of inorganic layers and disposed to overlap the light emitting element in the first opening.

10. The display device of claim 9, further comprising:
a first passivation layer disposed on the plurality of inorganic layers and the reflective layer;
a planarization layer disposed on the first passivation layer and having a second opening disposed therein and overlapping the light emitting element; and
a second passivation layer disposed on the planarization layer and the first passivation layer and in contact with the first passivation layer in the second opening.

11. The display device of claim 10, wherein the first assembly line and the second assembly line are disposed on the second passivation layer and are disposed in the first opening and the second opening.

12. The display device of claim 11, wherein portions of the first assembly line and the second assembly line disposed in the first opening and the second opening are formed of a transparent conductive material.

13. The display device of claim 10, wherein an upper surface of the planarization layer is disposed at a position higher than an upper surface of the light emitting element.

14. The display device of claim 9, wherein the reflective layer is formed of a same material as source electrodes or drain electrodes of the plurality of transistors.

15. The display device of claim 1, further comprising a high-potential power supply line disposed between the first area and the second area.

16. The display device of claim 9, wherein the reflective layer is disposed to cover a bottom and a side portion of the first opening so as to reflect light emitted from the light emitting element to a front direction of the display device.

17. The display device of claim 1, wherein the first assembly line and the second assembly line are disposed to be spaced apart from the plurality of transistors.
